(19) United States
(12) Patent Application Publication
(10) Pub. No.: US 2015/0083480 A1
(43) Pub. Date: Mar. 26, 2015

(54) INTERPOSER BOARD AND METHOD OF MANUFACTURING THE SAME

(71) Applicant: Samsung Electro-Mechanics Co., Ltd., Wuwon-si (KR)

(72) Inventors: Seon Hee MOON, Suwon-si (KR); Seung Wook Park, Suwon-si (KR); Chang Bae Lee, Suwon-si (KR)

(73) Assignee: Samsung Electro-Mechanics Co., Ltd., Suwon-si (KR)

(21) Appl. No.: 14/143,536

(22) Filed: Dec. 30, 2013

(30) Foreign Application Priority Data
Sep. 25, 2013 (KR) 10-2013-0113967

(51) Int. Cl. H05K 1/11; H05K 3/46; H05K 3/42

(52) U.S. Cl. CPC H05K 1/116; H05K 3/429; H05K 3/4647; H05K 2201/09509; H05K 2201/0959
USPC 174/264; 29/852

(57) ABSTRACT

Disclosed herein are an interposer board and a method of manufacturing the same. According to a preferred embodiment of the present invention, the interposer substrate may include: a base substrate; a circuit pattern formed on the base substrate; and a through via formed to penetrate through the base substrate and have a height lower than that of the circuit pattern.

### CROSS REFERENCE TO RELATED APPLICATION

This application claims the benefit of Korean Patent Application No. 10-2013-0113967, filed on Sep. 25, 2013, entitled “Interposer Board And Method Of Manufacturing The Same”, which is hereby incorporated by reference in its entirety into this application.

### BACKGROUND OF THE INVENTION

1. Technical Field

The present invention relates to an interposer board and a method of manufacturing the same.

2. Description of the Related Art

With the rapid development of a semiconductor technology, a semiconductor device has greatly grown. Further, the development for a semiconductor package, such as a system in package (SIP), a chip sized package (CSP), and a flip chip package (FCP) which are configured as a package by mounting electronic devices, such as the semiconductor device, on a printed circuit board in advance has been actively conducted.

With the fineness and high integration of the electronic device, the number of I/Os of the electronic devices is increased and the number of pads of the package board on which the electronic devices are mounted is increased accordingly. Therefore, a fine pitch of the package board is required. Since the fine pitch of the package board leads to an increase in manufacturing cost of the package board, a problem of the fine pitch of the package board has overcome by interposing an interposer between the electronic device and the package board (U.S. Pat. No. 6,861,288).

### SUMMARY OF THE INVENTION

The present invention has been made in an effort to provide an interposer board and a method for manufacturing the same capable of preventing a short-circuit between a through via and a build-up circuit layer.

According to a preferred embodiment of the present invention, there is provided an interposer board, including: a base substrate; a circuit pattern formed on the base substrate; and a through via formed to penetrate through the base substrate and have a height lower than that of the circuit pattern.

An inside of the through via may be filled with a filler and may be formed to have a height lower than that of a side wall thereof.

An edge of an inside of the through via may be formed to have a height lower than that of a center thereof.

An inside of the through via may be made of a conductive material or a non-conductive material.

An inside of the through via may be made of a photosensitive insulating material.

The base substrate and the circuit pattern may be further provided with a build-up layer which includes a build-up insulating layer and a build-up circuit layer.

The build-up insulating layer and an inside of the through via may be made of the same material.

The build-up insulating layer may be made of a photosensitive insulating material.

A circuit layer formed in an inside of the through via and a circuit layer formed on a side wall thereof may be formed to have the same height.

According to another preferred embodiment of the present invention, there is provided a method for manufacturing an interposer board, including: preparing a base substrate on which a through hole is formed; forming a first plating layer on the base substrate and an inner wall of the through hole; filling a filler in the through hole to have a height lower than that of the inner wall of the through hole; forming a second plating layer in the first plating layer and the filler; and forming a circuit pattern and a through via by patterning the first plating layer and the second plating layer.

The first plating layer and the second plating layer may be made of a conductive material.

In the filling of the filler, the filler may be made of a conductive material or a non-conductive material.

In the filling of the filler, the filler may be made of a photosensitive insulating material.

The filling of the filler may include: filling the filler in the through hole; and etching the filler to have a height lower than that of the first plating layer.

The etching of the filler to have a height lower than that of the first plating layer may be performed by a plasma etching method, a chemical etching method, or exposure and developing.

In the filling of the filler, an edge of the filler may be filled to have a height lower than that of a center thereof.

In the forming of the circuit pattern and the through via, the through via may be formed to have a height equal to or lower than that of the circuit pattern.

The method for manufacturing an interposer board may further include: after the forming of the circuit pattern and the through via, forming a build-up layer including a build-up insulating layer and a build-up circuit layer in the circuit pattern and the through via.

In the forming of the build-up layer, the build-up insulating layer and an inside of the through via may be made of the same material.

In the forming of the build-up layer, the build-up insulating layer may be made of a photosensitive insulating material.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an exemplified diagram illustrating an interposer board according to a preferred embodiment of the present invention; and

FIGS. 2 to 11 are exemplified diagrams illustrating a method of manufacturing an interposer board according to a preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

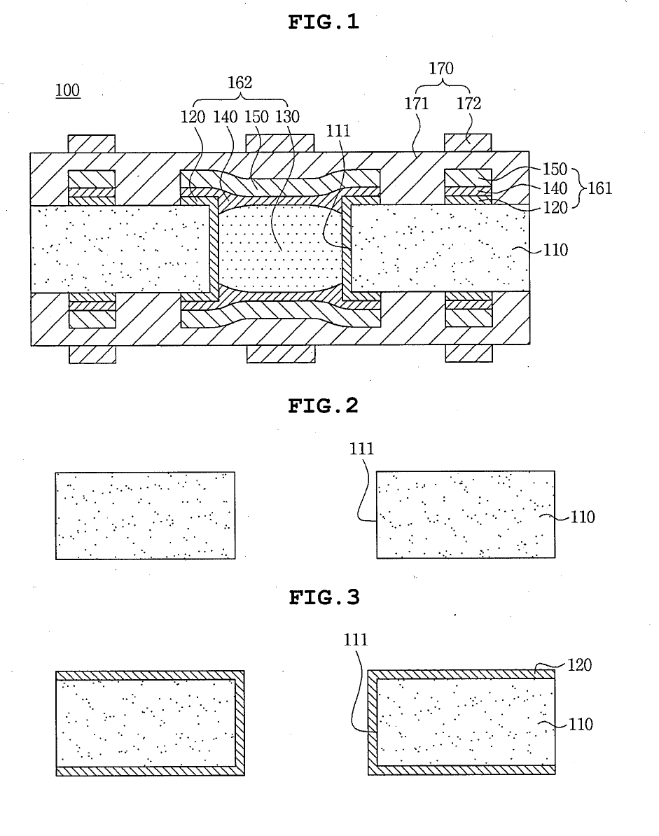

FIG. 1 is an exemplified diagram illustrating an interposer board according to a preferred embodiment of the present invention.

Referring to FIG. 1, an interposer board 100 may include a base substrate 110, a circuit pattern 161, a through via 162, and a build-up layer 170.

The base substrate 110 may be made of a composite polymer resin which is generally used as an interlayer insulating material. For example, the base substrate 110 adopts a prepreg, and thus the printed circuit board may be manufactured to be thinner. Alternatively, the base substrate 110 may adopt an ajinomoto build up film (ABF) to easily implement a fine circuit. In addition, the base substrate 110 may use an epoxy based resin, such as FR-4 and bismaleimide triazine (BT), but the preferred embodiment of the present invention is not particularly limited thereto. Further, the base substrate 110 may be formed using a copper clad laminate (CCL). The preferred embodiment of the present invention illustrates that the base substrate 110 is formed of a single insulating layer, but is not limited thereto. That is, the base substrate 110 may be a build-up layer which is configured to include at least one layer of insulating layer and circuit layer, and the via.

The circuit pattern 161 may be formed on the base substrate 110. The circuit pattern 161 may be made of a conductive material, such as copper. According to the preferred embodiment of the present invention, the circuit pattern 161 may be configured to include a first plating layer 120, a seed layer 140, and a second plating layer 150. This is the preferred embodiment of the present invention, but a configuration of the circuit pattern 161 is not limited thereto. That is, the configuration of the circuit pattern 161 may be changed depending on a method and a material for forming the circuit pattern 161.

The through via 162 may be formed to penetrate through the base substrate 110. That is, the through via 162 may be formed in a through hole 111 which penetrates through the base substrate 110. The through via 162 may be formed of the first plating layer 120, the seed layer 140, the second plating layer 150, and a filler 130. The first plating layer 120, the seed layer 140, and the second plating layer 150 of the through via 162 may be made of a conductive material, such as copper. The filler 130 of the through via 162 may be a conductive material or a non-conductive material. According to the preferred embodiment of the present invention, the filler 130 may be made of a photosensitive material. However, forming the filler 130 of the photosensitive material is by way of example only, and the preferred embodiment of the present invention is not limited thereto.

An inner wall of the through hole 111 may be provided with the first plating layer 120 which is a side wall of the through via 162. The through hole 111 in which the first plating layer 120 is formed may be filled with the filler 130 which is an inside of the through via 162. According to the preferred embodiment of the present invention, the filler 130 may be formed to have a height lower than that of the first plating layer 120 which is formed on the base substrate 110. That is, the inside of the through via 162 may be formed to have a height lower than that of the side wall thereof. In this case, when the filler 130 is filled in the through hole 111 and etched using plasma, an edge of the filler 130 may be more etched than a center thereof. That is, an edge of the inside of the through via 162 is formed to have a height lower than that of a center thereof, such that a section thereof may have the same shape as a ring.

The seed layer 140 and the second plating layer 150 of the through via 162 may be formed on the first plating layer 120 and the filler 130 to serve as a via pad. Since the filler 130 is formed to be lower than the first plating layer 120, the seed layer 140 and the second plating layer 150 may also be formed to have a step. That is, a portion in which the seed layer 140 and the second plating layer 150 are formed in the filler 130 may be lower than the first plating layer 120.

The build-up layer 170 may be formed in the circuit pattern 161 and the through via 162. Further, the build-up layer 170 may include a build-up insulating layer 171 and a build-up circuit layer 172.

The build-up insulating layer 171 may be formed to bury the circuit pattern 161 and the through via 162. The build-up insulating layer 171 may be made of the photosensitive insulating material. However, the build-up insulating layer 171 is made of only the photosensitive insulating material, but any insulating material used in a field of the board may be used.

The build-up circuit layer 172 may formed on the build-up insulating layer 171. The build-up circuit layer 172 may be made of a conductive material, such as copper.

According to the preferred embodiment of the present invention, the through via 162 may be formed to have a height equal to or lower than that of the circuit pattern 161 therearound. The through via 162 may be formed to be sufficiently spaced apart from the build-up circuit layer 172 which is formed thereon. Therefore, in the interposer board 100 according to the embodiment of the present invention, an insulating distance between the through via 162 and the build-up circuit layer 172 may be sufficiently secured, and thus the occurrence of a short-circuit therebetween may be prevented.

FIGS. 2 to 11 are exemplified diagrams illustrating a method of manufacturing an interposer board according to a preferred embodiment of the present invention.

Referring to FIG. 2, the base substrate 110 may be prepared.

The base substrate 110 may be made of a composite polymer resin generally used as an interlayer insulating material. For example, the base substrate 110 adopts a prepreg, and thus the printed circuit board may be manufactured to be thinner. Alternatively, the base substrate 110 may adopt an ajinomoto build up film (ABF) to easily implement a fine circuit. In addition, the base substrate 110 may use the epoxy based resin, such as FR-4 and bismaleimide triazine (BT), but the preferred embodiment of the present invention is not particularly limited thereto. Further, the base substrate 110 may be formed using the copper clad laminate (CCL). The preferred embodiment of the present invention illustrates that the base substrate 110 is formed of the single insulating layer, but is not limited thereto. That is, the base substrate 110 may be the build-up layer which is configured to include at least one layer of insulating layer and circuit layer, and the via.

The base substrate 110 may be provided with the through hole 111. The through hole 111 may be formed to penetrate through both surfaces of the base substrate 110. The through hole 111 may be formed by a CNC drill, a laser drill, or the like.

Referring to FIG. 3, the first plating layer 120 may be formed.

The first plating layer 120 may be formed on the base substrate 110 and the inner wall of the through hole 111. For example, the first plating layer 120 may be formed using an electroless plating method and an electroplating method. Further, the first plating layer 120 may be made of the conductive material, such as copper. The first plating layer 120 formed in the inner wall of the through hole 111 may be the side wall of the through via (not illustrated) later.

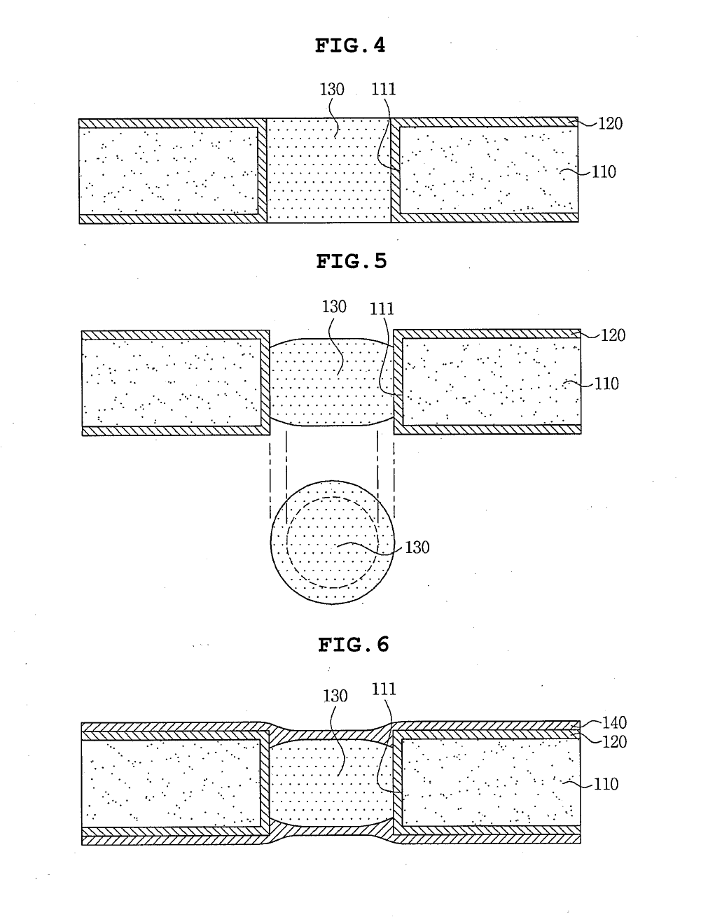

Referring to FIG. 4, the inside of the through hole 111 may be filled with the filler 130. According to the preferred embodiment of the present invention, the filler 130 may be made of the photosensitive insulating material. However, the material of the filler 130 is not limited to the photosensitive insulating material, but any of the conductive material and the non-conductive material which are used in the field of the board may be used. The filler 130 filled in the through hole 111 may be filled to have a height equal to or higher than that of the first plating layer 120 which is formed on the base substrate 110.

Referring to FIG. 5, the filler 130 may be etched.

The filler 130 filled in the through hole 111 may be etched to have a height lower than that of the first plating layer 120 which is formed on the base substrate 110. For example, the filler 130 may be etched by a plasma etching method, a chemical etching method, or exposure and developing. Herein, when the filler 130 is etched by the plasma etching method, the edge portion of the filler 130 may be over-etched than the center thereof in terms of the plasma characteristics. Therefore, the filler 130 etched by the plasma etching method may have a section such as the ring shape as illustrated in FIG. 5. In this case, the highest portion of the filler 130 may have a height lower than that of the first plating layer 120. That is, the center portion of the etched filler 130 may have a height lower than that of the first plating layer 120. Further, when the filler filled in the through hole 111 is etched, the filler 130 formed on the first plating layer 120 may also be removed by the etching.

Referring to FIG. 6, the seed layer 140 may be formed.

The seed layer 140 may be formed on the first plating layer 120 and the filler 130. The seed layer 140 may be formed by the electroless plating method. Further, the seed layer 140 may be made of the conductive material, such as copper. Herein, the height of the seed layer 140 formed on the filler 130 may be lower than that of the seed layer 140 formed on the first plating layer 120 due to a difference in the height between the filler 130 and the first plating layer 120.

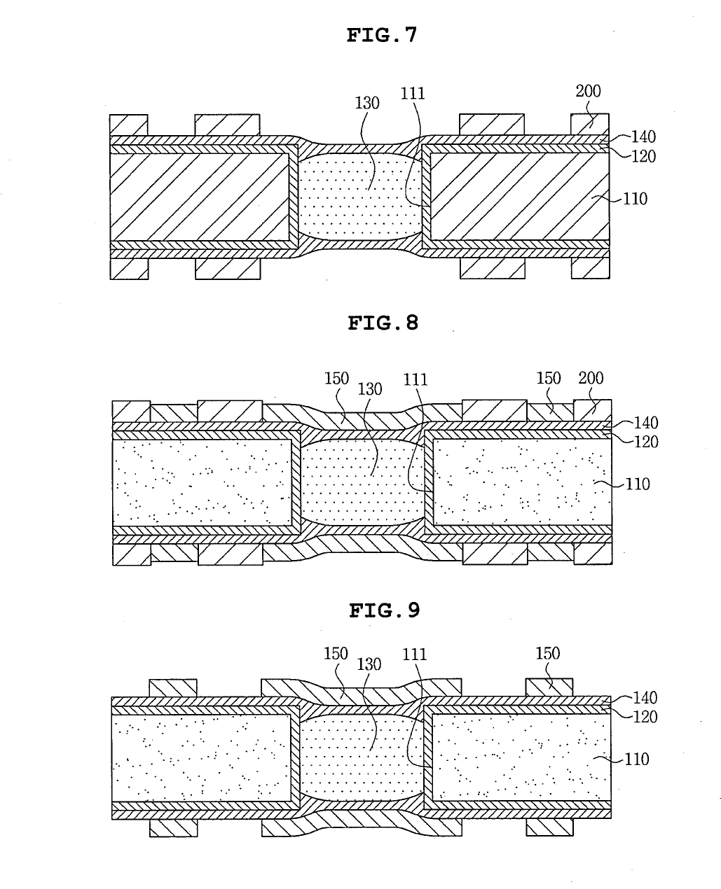

Referring to FIG. 7, the plating resist 200 may be formed.

The plating resist 200 may be patterned with an opening. The opening of the plating resist 200 may expose the seed layer 140 of an area in which the circuit pattern 161 is formed.

Referring to FIG. 8, the second plating layer 150 may be formed.

The second plating layer 150 may be formed on the opening of the plating resist 200. The second plating layer 150 may be formed by the electroplating method. Further, the second plating layer 150 may be made of the conductive material, such as copper. Herein, the second plating layer 150 formed over the filler 130 may have a height lower than that of the second plating layer 150 formed over the first plating layer 120 due to the difference in the height between the first plating layer 120 and the filler 130.

Referring to FIG. 9, the plating resist 200 (FIG. 7) may be removed.

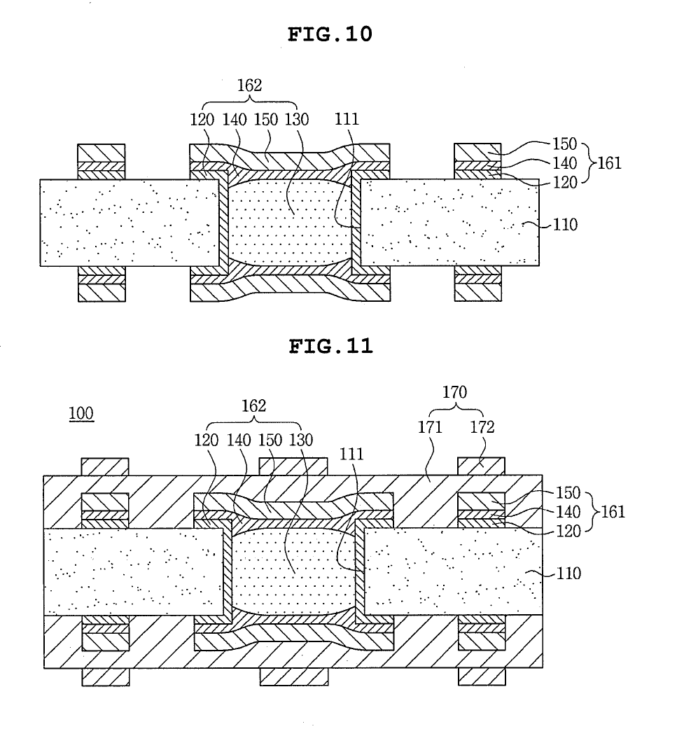

Referring to FIG. 10, the circuit pattern 161 and the through via 162 may be formed.

The plating resist 200 (FIG. 7) is removed and thus the exposed seed layer 140 may be removed. As the exposed seed layer 140 is removed, the circuit pattern 161 configured to include the first plating layer 120, the seed layer 140, and the second plating layer 150 may be formed on the base substrate 110. Further, the through hole 111 may be provided with the through via 162 which is configured to have the first plating layer 120, the seed layer 140, the second plating layer 150, and the filler 130. Herein, the height of the second plating layer 150 of the through via 162 may be equal to or lower than that of the second plating layer 150 of the circuit pattern 161.

Referring to FIG. 11, the build-up layer 170 may be formed.

The build-up layer 170 may include the build-up circuit layer 172 and the build-up insulating layer 171. The build-up layer 170 may be formed on the circuit pattern 161 and the through via 162. The build-up insulating layer 171 may be made of the photosensitive insulating material. However, the build-up insulating layer 171 is made of only the photosensitive insulating material, but any insulating material used in the field of the board may be used. The build-up circuit layer 172 may formed on the build-up insulating layer 171. The build-up circuit layer 172 may be made of the conductive material, such as copper.

In this case, since an upper surface (upper surface of the second plating layer) of the through via 162 is equal to or lower than that of the circuit pattern 161, even though a thickness of the build-up insulating layer 171 is thin, the short-circuit between the build-up circuit layer 172 and the through via 162 may be prevented.

According to the related art, even when the filler is filled in the through via and then suffers from a planarization process, the filler with respect to the base substrate may be overcharged without being completely planarized. When the filler is overcharged, the upper surface of the later formed through via is not planarized but may have a height higher than that of the circuit pattern therearound. The so formed through via and the build-up circuit layer formed thereon may not secure the sufficiency insulating distance and thus the short-circuit therebetween may occur. However, according to the preferred embodiment of the present invention, the through via is filled with the filler and then the inside (filler) of the through via may be over-etched. Therefore, the through via may be formed to have a height equal to or lower than that of the circuit pattern therearound. The insulating distance from the build-up circuit layer formed on the through via later is sufficiently secured by forming the through via as described above and thus the short-circuit therebetween may be prevented.

According to the interposer board and the method for manufacturing the same according to the preferred embodiments of the present invention, it is possible to prevent the short-circuit between the through via and the build-up circuit layer by over-etching the filler in the through via.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. An interposer board, comprising:
a base substrate;
a circuit pattern formed on the base substrate; and
a through via formed to penetrate through the base substrate and have a height lower than that of the circuit pattern.

2. The interposer board as set forth in claim 1, wherein an inside of the through via is filled with a filler and is formed to have a height lower than that of a side wall thereof.

3. The interposer board as set forth in claim 1, wherein an edge of an inside of the through via is formed to have a height lower than that of a center thereof.

4. The interposer board as set forth in claim 1, wherein an inside of the through via is made of a conductive material or a non-conductive material.

5. The interposer board as set forth in claim 1, wherein an inside of the through via is made of a photosensitive insulating material.

6. The interposer board as set forth in claim 1, wherein the base substrate and the circuit pattern are further provided with a build-up layer which includes a build-up insulating layer and a build-up circuit layer.

7. The interposer board as set forth in claim 6, wherein the build-up insulating layer and an inside of the through via are made of the same material.

8. The interposer board as set forth in claim 6, wherein the build-up insulating layer is made of a photosensitive insulating material.

9. The interposer board as set forth in claim 1, wherein a circuit layer formed in an inside of the through via and a circuit layer formed on a side wall thereof are formed to have the same height.

10. A method for manufacturing an interposer board, comprising:
preparing a base substrate on which a through hole is formed;
forming a first plating layer on the base substrate and an inner wall of the through hole;
filling a filler in the through hole to have a height lower than that of the inner wall of the through hole;
forming a second plating layer in the first plating layer and the filler; and
forming a circuit pattern and a through via by patterning the first plating layer and the second plating layer.

11. The method as set forth in claim 10, wherein the first plating layer and the second plating layer are made of a conductive material.

12. The method as set forth in claim 10, wherein in the filling of the filler, the filler is made of a conductive material or a non-conductive material.

13. The method as set forth in claim 10, wherein in the filling of the filler, the filler is made of a photosensitive insulating material.

14. The method as set forth in claim 10, wherein the filling of the filler includes:
filling the filler in the through hole; and
etching the filler to have a height lower than that of the first plating layer.

15. The method as set forth in claim 10, wherein the etching of the filler to have a height lower than that of the first plating layer is performed by a plasma etching method, a chemical etching method, or exposure and developing.

16. The method as set forth in claim 10, wherein in the filling of the filler, an edge of the filler is filled to have a height lower than that of a center thereof.

17. The method as set forth in claim 10, wherein in the forming of the circuit pattern and the through via, the through via is formed to have a height equal to or lower than that of the circuit pattern.

18. The method as set forth in claim 10, further comprising:
after the forming of the circuit pattern and the through via, forming a build-up layer including a build-up insulating layer and a build-up circuit layer in the circuit pattern and the through via.

19. The method as set forth in claim 18, wherein in the forming of the build-up layer, the build-up insulating layer and an inside of the through via are made of the same material.

20. The method as set forth in claim 18, wherein in the forming of the build-up layer, the build-up insulating layer is made of a photosensitive insulating material.
